(19) United States
(12) Patent Application Publication
(10) Pub. No.: US 2018/0374553 A1
(43) Pub. Date: Dec. 27, 2018

(54) SEMICONDUCTOR DEVICE

(71) Applicant: Renesas Electronics Corporation, Tokyo (JP)

(72) Inventor: Yasuaki WATANABE, Tokyo (JP)

(73) Assignee: Renesas Electronics Corporation, Tokyo (JP)

(21) Appl. No.: 15/977,521

(22) Filed: May 11, 2018

(30) Foreign Application Priority Data
Jun. 22, 2017 (JP) 2017-122004

(51) Int. Cl. G11C 16/34; G11C 16/10; G11C 11/4097

(52) U.S. Cl. CPC G11C 16/3459; G11C 11/4097; G11C 16/10

(57) ABSTRACT

In a multiple data continuous write to a non-volatile memory, a write determination is performed by eliminating as much as possible the effect of the amount of threshold variation due to electron-hole recombination generated in a write operation of a memory cell. It is controlled so that a cycle (t_{w}) of performing a write operation on a memory cell in a write operation and a cycle (tᵥ+t_{w}−tᵥ) of performing a write verify operation on a memory cell in a write verify operation are the same. Alternatively, as address advances from a first address to the nth address (n is an integer) where continuous write is performed, a determination condition in the write verify operation is made severer.

### CROSS-REFERENCE TO RELATED APPLICATIONS

The disclosure of Japanese Patent Application No. 2017-122004 filed on Jun. 22, 2017 including the specification, drawings and abstract is incorporated herein by reference in its entirety.

### BACKGROUND

The present invention relates to a semiconductor device mounted with a non-volatile memory.

When writing data to a non-volatile memory, a write operation which applies a write voltage to a memory cell and raises a threshold voltage of the memory cell and a write verify operation which confirms that the threshold voltage of the memory cell is raised to a predetermined threshold voltage or more by the write operation are performed. The threshold voltage of an erase cell is low, so that when the amount of current flowing through a memory cell exceeds a reference current by applying a predetermined read voltage to a word line, data “1” is read. On the other hand, data “0” is read from a write cell by applying a predetermined read voltage to a word line. However, the threshold voltage of the write cell is high, so that the amount of current flowing through a memory cell does not exceed the reference current. In order to suppress the effects of aging variation and reliably read data “0” from the write cell, it is necessary to perform write so that the threshold voltage is higher than a threshold voltage where a reference current value flows during a read operation. As factors for considering the size of margin, there are a manufacturing variation, an aging variation of a memory cell threshold value, and the like. Japanese Unexamined Patent Application Publication No. 2005-327359 discloses a technique that performs a read/write verify operation corresponding to a manufacturing variation and an aging variation of the memory cell threshold value. Specifically, when the write verify fails, a write verify level is alleviated until the write verify is successfully performed. To normally read a write cell, a certain gap is required between the write verify level and a read determination level, so that it is necessary to vary the read determination level interlocking with the write verify level.

On the other hand, high-speed writing to a non-volatile memory is also a big problem. In the write operation, a high voltage is applied to a source line of a memory cell. On the other hand, in the write verify operation, the source line is discharged to 0 V (standard potential). A plurality of memory cells are coupled to the source line, so that a certain time is required for charge and discharge. Therefore, when repeating the write operation and the write verify operation for each memory cell, charge and discharge of the source line occur every time data is written, so that a write time increases.

To reduce the write time, a multiple data continuous write is generally performed. The multiple data continuous write is a method of continuously performing write operations on a plurality of memory cells and thereafter continuously performing verify operations. The multiple data continuous write is performed on a plurality of memory cells coupled to the same source line. Therefore, while the write operations are continuously performed or while the write verify operations are continuously performed, the charge and discharge of the source line do not occur. Hence, the number of times of switching between the write operation and the write verify operation decreases (that is, the number of times of charge and discharge of the source line decreases), and the write time can be reduced accordingly.

When writing random data such as programs and data, the greater the number of data to be continuously written at once, the shorter the write time. However, this requires a large buffer, so that a circuit area increases. The buffer is used to store an expectation value to be collated with data read from a write cell during the write verify operation. Therefore, in general, the continuous write is performed for about four to eight data from a trade-off between a write time reduction effect and a circuit area.

### SUMMARY

Japanese Unexamined Patent Application Publication No. 2005-327359 discloses a technique that rationalizes the write verify operation corresponding to variation and aging of the memory cell threshold value. On the other hand, when performing the multiple data continuous write for high-speed writing to a non-volatile memory, there is a risk that the verify operation may be affected as described later.

In a non-volatile memory cell, recombination of electrons and holes localized in a trap site begins from immediately after completion of the write operation. Thereby, the memory cell threshold voltage begins to significantly drop after the completion of the write operation. Although this phenomenon occurs also in a floating gate type memory cell, this phenomenon occurs remarkably in a MONOS type memory cell. Further, as the number of rewriting times increases, the number of trap sites increases. Therefore, a decreasing amount and a decreasing degree of the memory cell threshold voltage are gradually increasing from immediately after completion of write.

Generally, a time required for a write operation of one memory cell is longer than a time required for a write verify operation of one memory cell. While the write verify operation is basically as quick as the read operation, the write operation requires an injection of a certain amount of charge into a memory cell (a floating gate in the case of a floating gate type memory cell, and a nitride film in the case of a MONOS type memory cell). Therefore, the write operation requires time for the injection.

FIG. 1 shows an example of a timing chart when four data are continuously written. It is common that a time from completion of a write operation to start of a verify operation varies by address. Hereinafter, the invention will be described with reference to FIG. 1. The time from completion of the write operation to start of the verify operation is time t0 (=3t_{w}) in the case of a memory cell of address 0, time t1 (=2t_{w}+tᵥ) in the case of a memory cell of address 1, time t2 (32 1t_{w}+2tᵥ) in the case of a memory cell of address 2, and time t3 (=3tᵥ) in the case of a memory cell of address 3. As the address advances, time from the completion of the write operation to the start of the write verify operation decreases. Considering visibility of FIG. 1, time t_{w} required for a write operation of one address and time tᵥ required for a write verify operation of one address do not correspond to an actual ratio. Actually, the time t_{w} is 5 to 10 μs, and the time tᵥ is about 1 μs. When the multiple data continuous write is performed in this way, the time from immediately after the completion of the write operation to the start of the verify operation varies by memory cell. More specifically, when the multiple data continuous write is performed, a threshold decreasing amount caused by electron-hole recombination generated from immediately after the completion of the write operation significantly varies for each memory cell due to the difference of the time from the completion of the write operation to the start of the write verify operation.

FIG. 2 schematically shows time variation of the memory cell threshold value from the completion of the write operation. FIG. 2 illustrates two memory cells. The threshold voltages of a memory cell A00 of address 0 and a memory cell A03 of address 3 rise to Vini by a write operation and thereafter fall. A curve 201 shows a fall of the threshold voltage of the memory cell A00. A curve 202 (solid line) shows a case in which the threshold voltage of the memory cell A03 falls at the same rate as the threshold voltage of the memory cell A00. A curve 203 (dashed-dotted line) shows a case in which the threshold voltage of the memory cell A03 falls faster than the memory cell threshold value of the memory cell A00.

In the memory cell A00, the write operation is completed at time two and the write verify is performed at time Tv0. In the memory cell A03, the write operation is completed at time tw3 and the write verify is performed at time Tv3. In this case, at a time point when the write verify is performed, the threshold voltage of the memory cell A00 of address 0 is V0 and the threshold voltage of the memory cell A03 of address 3 is V3a (in the case of the curve 202) or V3b (in the case of the curve 203). The time from the completion of the write operation to the start of the write verify operation is different between the memory cell A00 and the memory cell A03 (Tv0−Tw0 >Tv3−Tw3), so that even when the memory cell threshold values fall at the same rate, V0<V3a is established. In other words, the greater the number of data where the multiple data continuous write is performed or the earlier the data is written, the greater the amount of variation of the threshold voltage during the write verify operation, so that it is highly possible that the verify fails. This causes a reduction of a production yield. Even when the threshold voltage falls as shown by the curve 203, if the fall is within a level where the fall does not affect the read operation on a long-term basis, there is no problem to perform quality determination on the memory cell A03 by using a determination voltage Vth2. However, the memory cell A00 is determined as failure because the threshold voltage V0 <the determination voltage Vth2 is established at time Tv0, and even if the data holding characteristics of the memory cell A00 are superior to those of the memory cell A03, the memory cell A00 may be determined as write failure.

On the other hand, when a determination criterion of the write verify is relaxed to a determination voltage Vth1, even if the fall of the threshold voltage of the curve 203 is a level where written data cannot be read on a long-term basis, the memory cell A03 is determined to be good because the threshold voltage V3b>the determination voltage Vth1 is established, so that the reliability of the memory cell degrades.

It is desired that a write determination is appropriately performed by eliminating as much as possible the effect of the amount of variation of the threshold voltage due to such electron-hole recombination. The other problems and novel features will become apparent from the description of the present specification and the accompanying drawings.

When the multiple data continuous write is performed on a non-volatile memory, it is controlled so that a cycle of performing a write operation on a memory cell in the write operation and a cycle of performing a write verify operation on a memory cell in the write verify operation are the same.

It is possible to determine continuously-written data with an appropriate determination level, so that the yield rate and reliability of non-volatile semiconductor memory circuits are improved.

### BRIEF DESCRIPTION OF THE DRAWINGS

FIG. 1 is an example of a timing chart when four data are continuously written in a related art.

FIG. 2 is a diagram for explaining a problem of the present invention.

FIG. 3 is an entire configuration of a semiconductor device.

FIG. 4 is a diagram showing a configuration of a non-volatile memory macro of a first embodiment.

FIG. 5A is a diagram showing a configuration of a memory cell array.

FIG. 5B is a diagram showing voltages applied to each terminal of a memory cell in each mode.

FIG. 6 is a diagram showing a configuration of an X decoder.

FIG. 7 is a diagram showing a configuration of a driver.

FIG. 8 is a diagram showing a configuration of a Y selector.

FIG. 9 is a diagram showing a configuration of a sense amplifier.

FIG. 10 is a diagram showing a configuration of a reference current generation circuit.

FIG. 11 is a diagram showing a configuration of a high voltage generation circuit.

FIG. 12 is a flowchart of continuous data write.

FIG. 13 is a timing chart of continuous data write in the first embodiment.

FIG. 14 is a diagram showing a configuration of a non-volatile memory macro of a second embodiment.

FIG. 15 is a diagram showing a configuration of a high voltage generation circuit.

FIG. 16 is a flowchart of continuous data write in the second embodiment.

FIG. 17 is a diagram showing a configuration of a non-volatile memory macro of a third embodiment.

FIG. 18 is a diagram showing a configuration of a reference current generation circuit.

FIG. 19 is a flowchart of continuous data write in the third embodiment.

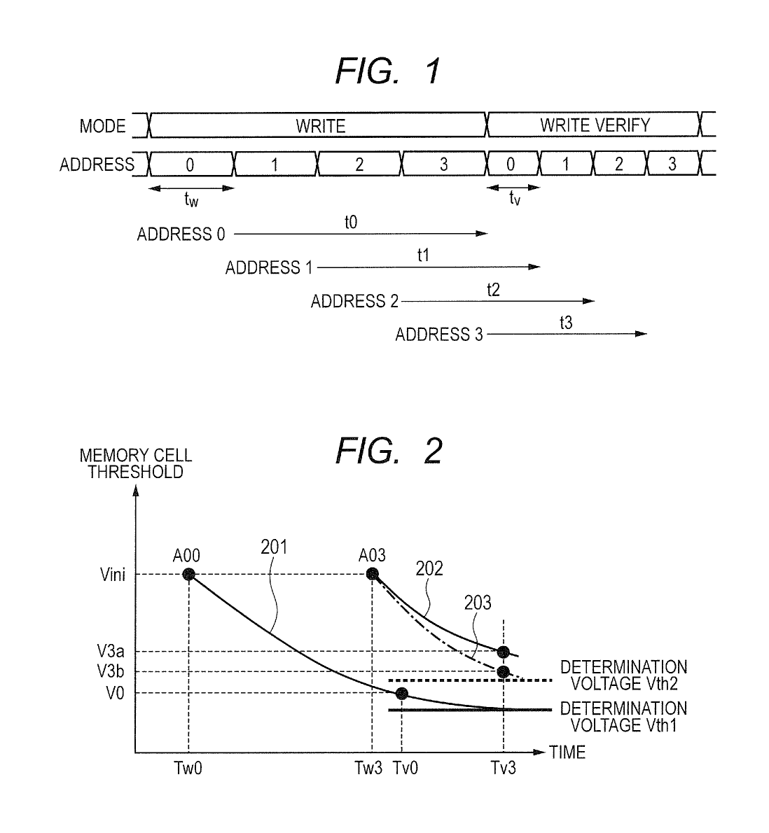

### DETAILED DESCRIPTION

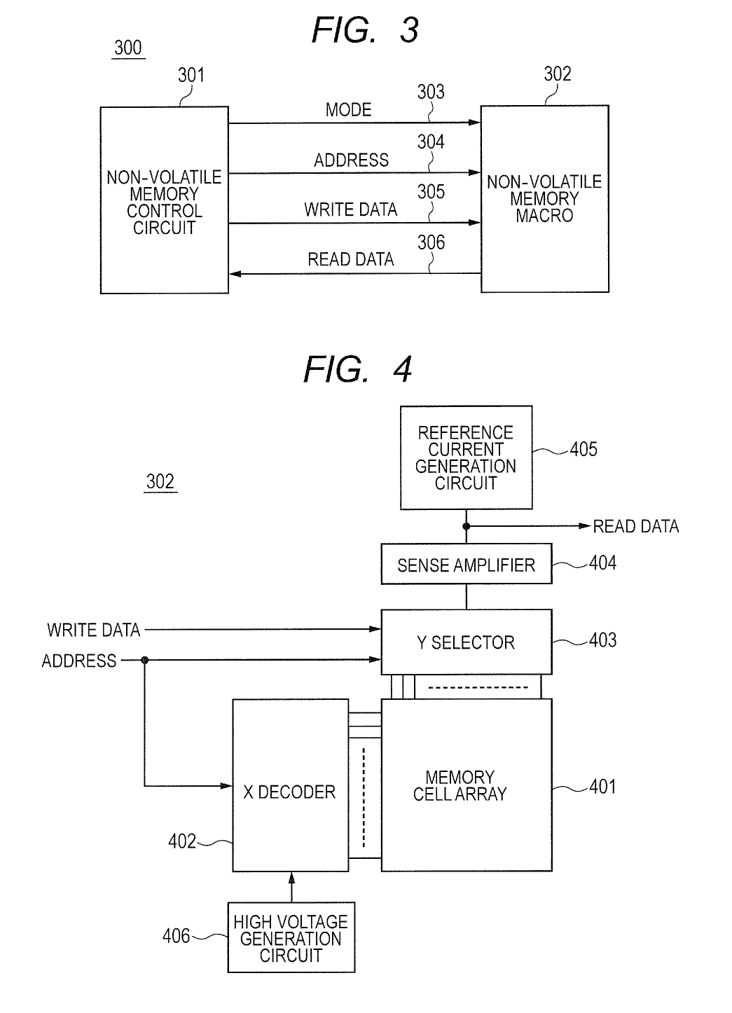

FIG. 3 shows a configuration of a semiconductor device 300 according to an embodiment. The semiconductor device 300 has a non-volatile memory control circuit 301 and a non-volatile memory macro 302. The non-volatile memory control circuit 301 is a circuit that controls the non-volatile memory macro 302. A mode signal 303 specifies a mode such as read, write, erase, write verify, or the like of the non-volatile memory. An address signal 304 specifies address information of a memory cell where a mode such as read, write, or the like is specified by the mode signal 303. A write data signal 305 is write data to be written to the non-volatile memory macro 302. A read data signal 306 is read data that is read from the non-volatile memory macro 302.

### First Embodiment

FIG. 4 shows a configuration of the non-volatile memory macro (non-volatile memory circuit) 302. The non-volatile memory macro 302 has a memory cell array 401, an X decoder 402, a Y selector 403, a sense amplifier 404, a reference current generation circuit 405, and a high voltage generation circuit 406.

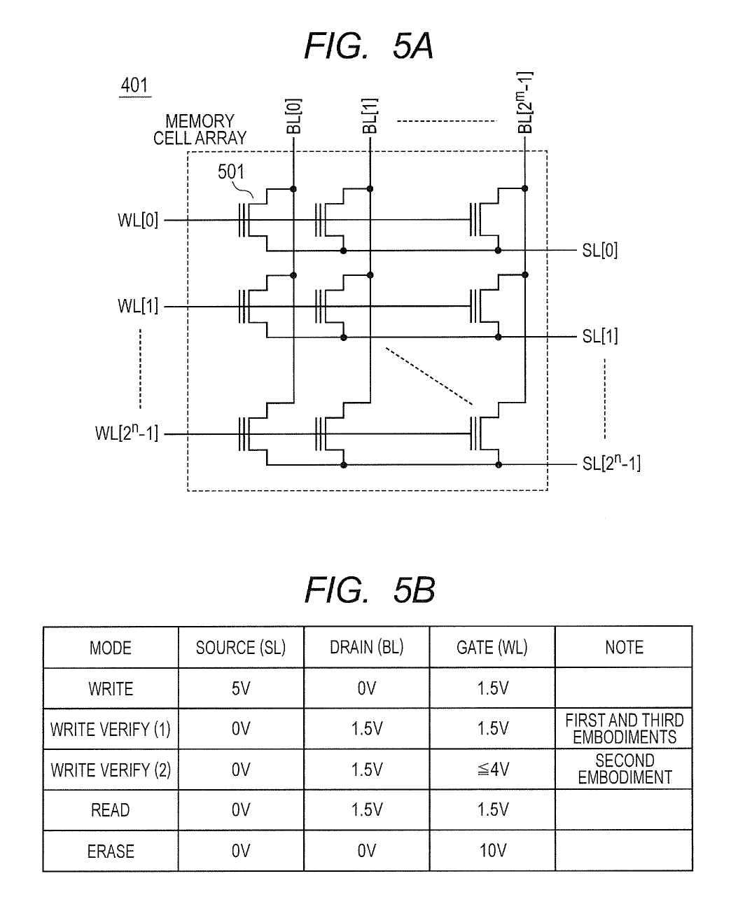

FIG. 5A shows a configuration of the memory cell array 401. A memory cell 501 is a non-volatile memory cell and has a charge holding layer for storing data. The charge holding layer may be a floating gate (a floating gate type memory cell) or may be an insulating film (a MONOS type memory cell). The drain of the memory cell 501 is coupled to a bit line BL, the source is coupled to a source line SL, and the gate is coupled to a word line WL. In the example of FIG. 5A, the sources of the memory cells 501 arranged in a row direction (horizontal direction) are coupled to a source line SL[j] (j=0 to 2ⁿ−1), and the gates of the memory cells 501 are coupled to a word line WL[i] (i=0 to 2ⁿ−1). The drains of the memory cells 501 arranged in a column direction (vertical direction) are coupled to a bit line BL[k] (k=0 to 2^{m}−1). FIG. 5B shows voltage examples applied to each terminal of a memory cell in each mode of write, write verify, read, and erase of the memory cell 501. Although the power supply voltage of the semiconductor device is not limited in particular, the power supply voltage is 1.5 V in this example. Although not shown in FIG. 4, the source line SL[j] (j=0 to 2ⁿ−1) is coupled to a source line decoder (SL decoder). The SL decoder selects a source line SL where a high voltage is applied when a write operation is performed. The write verify (1) is a case of the present embodiment and a third embodiment described below, and the write verify (2) is a case of a second embodiment described later. In the write verify (1), the same voltage as a read voltage Vrd is applied to a gate (word line WL), and a current flowing through a memory cell and a reference current Iref1 are compared. On the other hand, in the write verify (2), a write verify voltage Vvw, which is higher than the read voltage Vrd, is applied to a gate (word line WL), and a current flowing through a memory cell and a reference current Iref2 are compared. Here, by performing setting so that the reference current Iref2 is greater than the reference current Iref1, write determination can be performed by using the same memory cell threshold value.

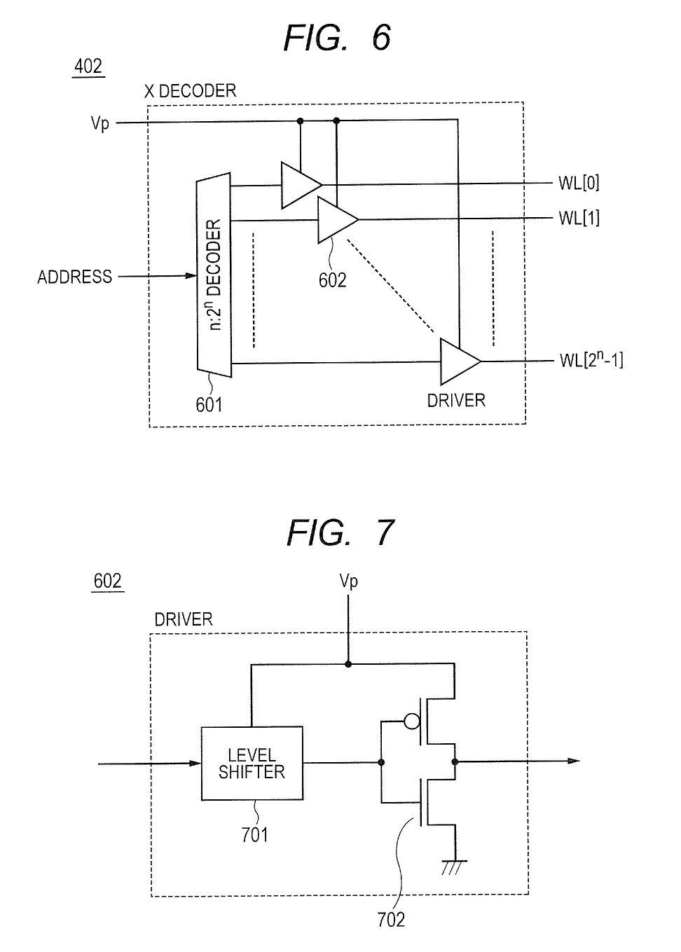

FIG. 6 shows a configuration of the X decoder 402. The X decoder 402 has a decoder 601 and a plurality of drivers 602. The decoder 601 decodes an X address of n bits into 2ⁿ bits. The driver 602 is coupled to each of 2ⁿ outputs of the decoder 601, and each driver drives the word line WL[i] (i=0 to 2ⁿ−1). The driver 602 is applied with a word line voltage Vp according to each mode. As shown in FIG. 5B, during reading, the power supply voltage is applied as the word line voltage Vp, and during a write verify (2) operation or during erasing, a predetermined high voltage is applied as the word line voltage Vp. FIG. 7 shows a configuration of the driver 602. The driver 602 has a level shifter 701 and a logic circuit 702 (an inverter in the example of FIG. 7) that outputs a voltage of high/low level according to an output signal of the decoder 601. The level shifter 701 is provided to convert amplitude of the output signal from the decoder 601 of a power supply voltage VDD level (for example, 1.5 V) into amplitude of a word line voltage Vp level.

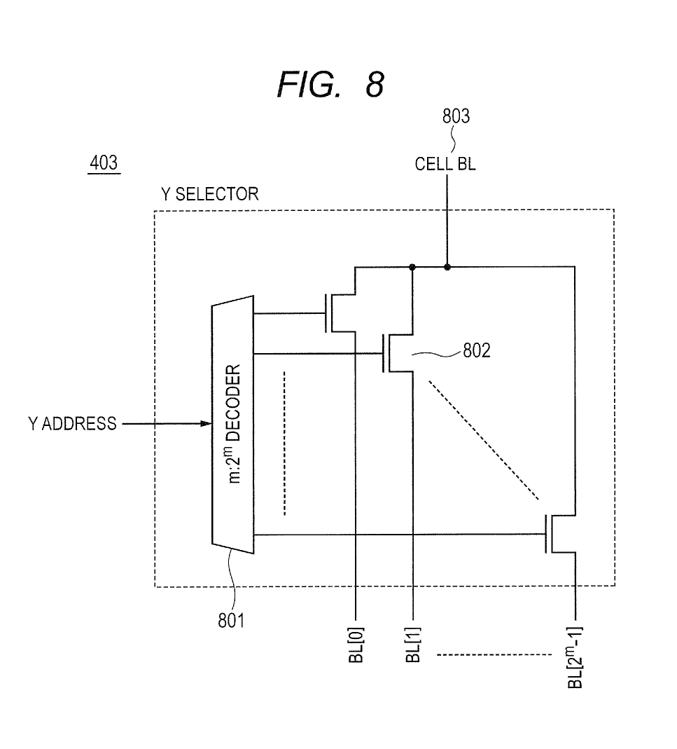

FIG. 8 shows a configuration of the Y selector 403. The Y selector 403 has a decoder 801 and a plurality of transistors 802. For example, the decoder 801 is an m:2^{m} decoder that decodes an Y address of m bits into 2^{m} bits and selectively makes a transistor 802 corresponding to the decoded Y address conductive. In read mode, the decoder 801 decodes an Y address of m bits into 2^{m} bits and selects a bit line BL. In write mode, when write data indicated by the write data signal 305 inputted into Y address is “0”, the decoder 801 decodes an Y address of m bits into 2^{m} bits so that a write current is flown to the memory cell. When the write data is “1”, the decoder 801 makes all the bit lines BL non-selective.

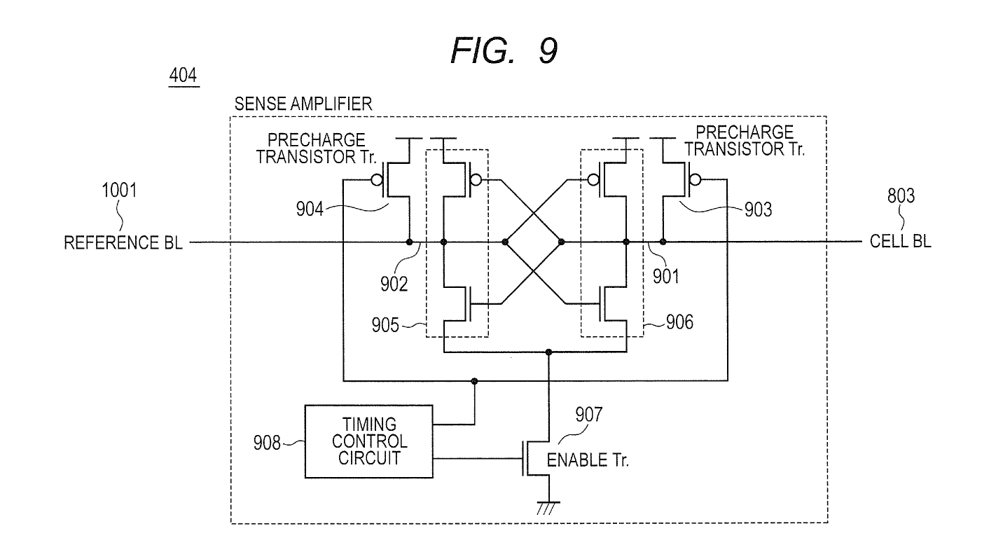

FIG. 9 shows a configuration of the sense amplifier 404. A cell bit line (cell BL) 803 is coupled to a first input terminal 901 of the sense amplifier 404, and a reference bit line (reference BL) 1001 is coupled to a second input terminal 902. The cell BL 803 is an output of the bit line BL selected by the Y selector 403 (see FIG. 8), and the reference BL 1001 is an output of the reference current generation circuit 405. A source-drain path of a first precharge transistor 903 is coupled between the first input terminal 901 and a power supply potential, and a source-drain path of a second precharge transistor 904 is coupled between the second input terminal 902 and the power supply potential. The sense amplifier is a cross-coupled type sense amplifier. In the sense amplifier, a first inverter 905 coupled to the first input terminal 901 and a second inverter 906 coupled to the second input terminal 902 are cross-coupled, sources of P-type MOS transistors of both inverters are coupled to the power supply potential, and sources of N-type MOS transistors are commonly coupled and coupled to a standard potential (ground potential) through a source-drain path of an enable transistor 907. ON/OFF of the precharge transistors 903 and 904 and the enable transistor 907 is controlled by a timing control circuit 908.

In the read mode, the timing control circuit 908 makes the precharge transistors 903 and 904 into an ON state, precharges the cell BL (the first input terminal 901) and the reference BL (the second input terminal 902) to the power supply voltage, and thereafter makes both precharge transistors into an OFF state. During this time, the enable transistor 907 is kept in the OFF state, so that the potentials of the first input terminal 901 and the second input terminal 902 are kept at the power supply potential without change. After a lapse of a certain period of time, when the enable transistor 907 is made into ON state, by an effect of the cross-coupled inverters, a potential of an input terminal of higher voltage rises to the power supply potential, and a potential of an input terminal of lower voltage falls to the standard potential. It is set so that a reference current is greater than a cell current of an erase cell whose threshold value is low and is smaller than a cell current of a write cell whose threshold value is high. Therefore, when the memory cell selected by the Y selector 403 is an erase cell, the cell current is greater than the reference current, so that the cell BL is the standard potential, the reference BL is the power supply potential, and data “1” is outputted as read data. When the memory cell selected by the Y selector 403 is a write cell, the cell current is smaller than the reference current, so that the cell BL is the power supply potential, the reference BL is the standard potential, and data “0” is outputted as read data.

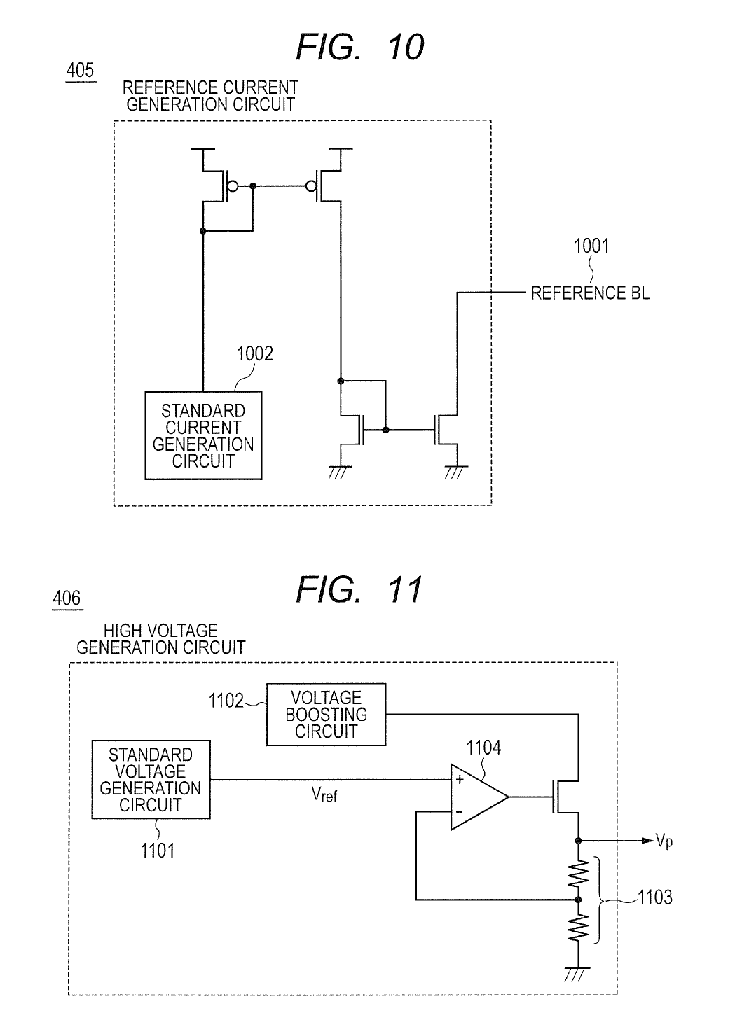

FIG. 10 shows a configuration of the reference current generation circuit 405. A standard current is generated by a standard current generation circuit 1002, the standard current is converted to a desired magnification by a current mirror, and a predetermined reference current is flown through the reference BL 1001.

FIG. 11 shows a configuration of the high voltage generation circuit 406. A standard voltage generation circuit 1101 generates a standard voltage Vref, a high voltage is generated by a voltage boosting circuit 1102. A voltage obtained by dividing the generated high voltage Vp by a resistor 1103 is compared with the standard voltage Vref. When the voltage is lower than the standard voltage, an output of a comparator 1104 turns ON. When the generated voltage rises and becomes higher than the standard voltage, the output of the comparator 1104 turns OFF and the generated voltage decreases. Thereby, the generated high voltage is kept constant regardless of output load.

While the circuit configuration of the non-volatile memory macro 302 has been described above, the circuit configuration can be variously changed. For example, reading speed can be increased by dividing the memory cell array 401 into a plurality of blocks in a column direction. When the memory cell array 401 is divided into 2^{p} blocks, a Y selector transistor 802 that selects 2^{(m-p)} bit lines BL is provided corresponding to each block and a Y selector transistor 802 group corresponding to each block is commonly controlled by a decoder that decodes lower (m−p) bits of the Y address into 2^{(m-p)} bits, so that one bit line BL can be selected in each block. In this case, the sense amplifier 404 is provided corresponding to each of the plurality of blocks, and a reference bit line is coupled to each sense amplifier.

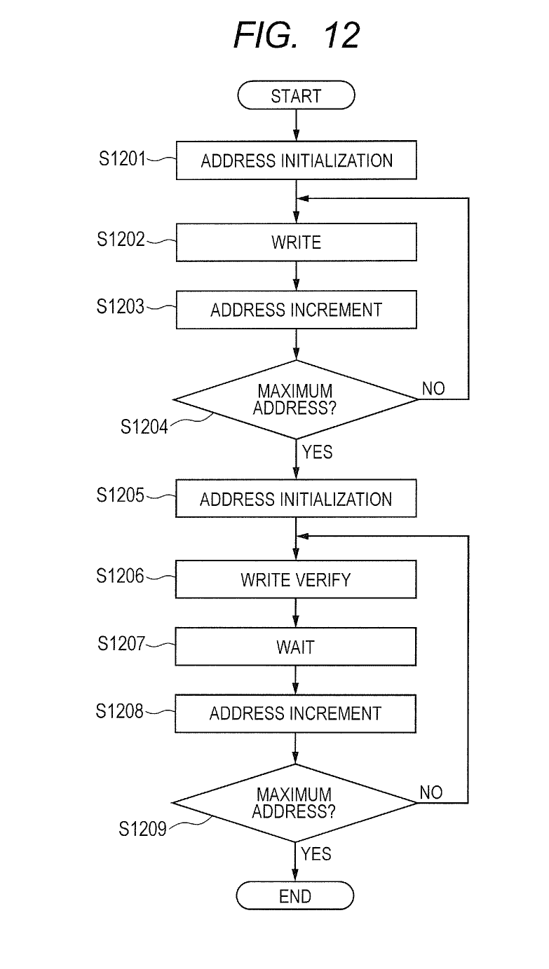

FIG. 12 shows a flowchart executed by the non-volatile memory control circuit 301 when a multiple data continuous write is performed on the non-volatile memory macro 302 in the semiconductor device 300. First, an address is set to a write start address (S1201), and write (S1202) and address increment (S1203) are repeated the number of times of the number of write data (S1204). When predetermined continuous data write is completed, the address is set to the write start address again (S1205), and write verify (S1206), predetermined time wait (S1207), and address increment (S1208) are repeated the number of times of the number of write data (S1209). Here, the predetermined time in step S1207 is set as “time required to perform write on one memory cell-time required to perform write verify on one memory cell”.

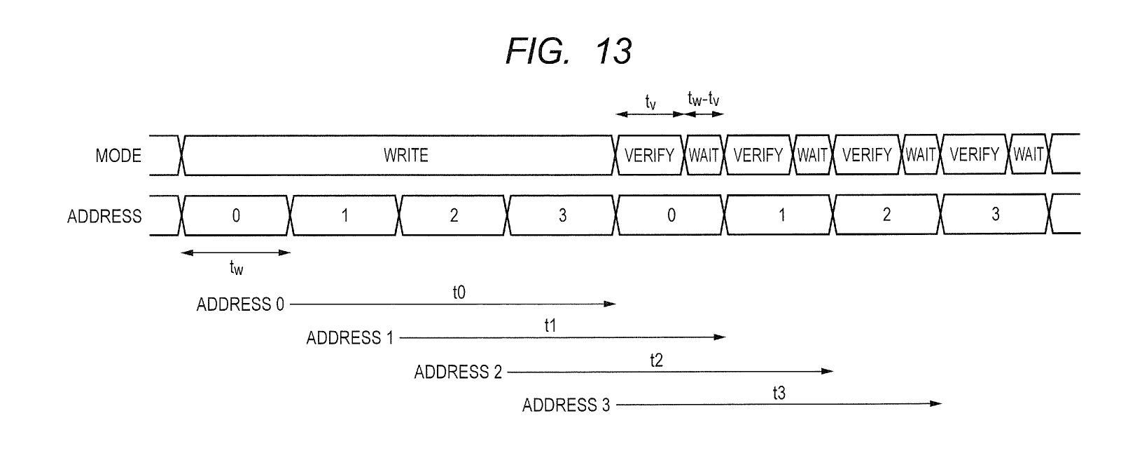

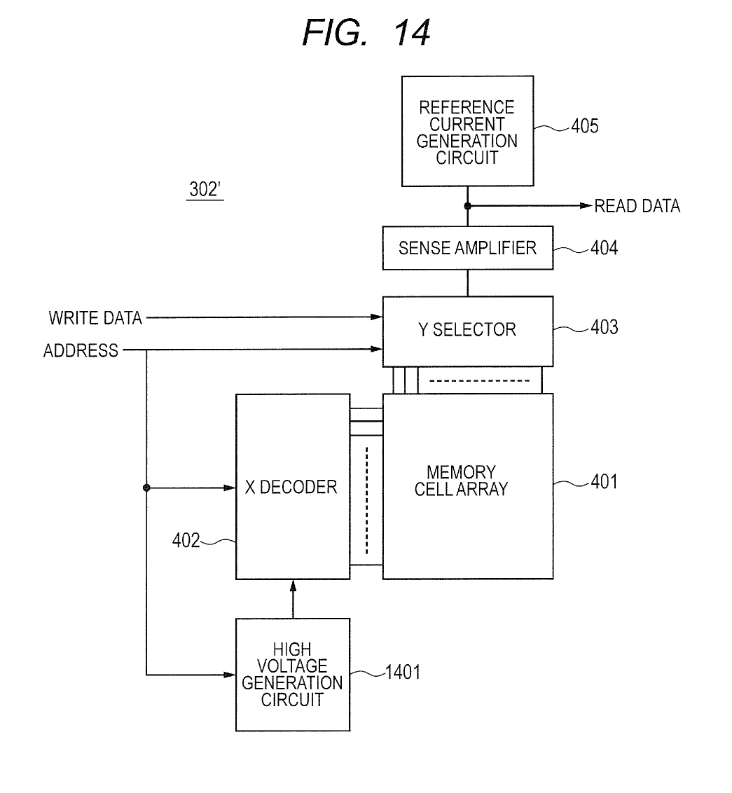

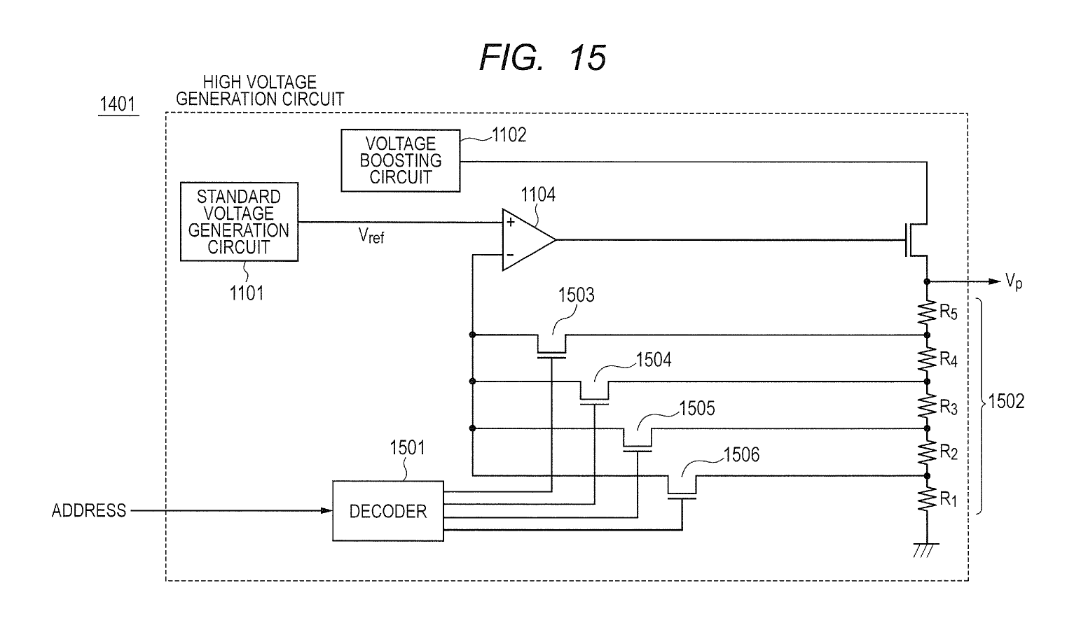

FIG. 13 shows a timing chart of multiple data continuous write in the first embodiment. Here, an example of four data continuous write is shown. It is defined so that time required for one data write is t_{w}, time required for one data write verify is tᵥ, and wait time is t_{w}−tᵥ. Thereby, a cycle of performing write on one memory cell and a cycle of performing write verify on one memory cell can be the same t_{w}. Thereby, time from a write operation completion to a verify operation start can be the same for four data that are continuously written (t0=t1=t2=t3=t_{w}). Thereby, it is possible perform determination with a constant margin regardless of an address where continuous write is performed.

As described above by using FIG. 2, the memory cell threshold value from the write operation completion varies with time. In the multiple data continuous write in the first embodiment, the time from the write operation completion to the verify operation start can be the same at any address. Therefore, when it is assumed that the memory cell at each address degrades at the same rate, it is possible to perform determination by using the same threshold value. In other words, it is possible to determine a determination voltage without individually considering the time variation of the memory cell threshold value from the write operation completion.

### Second Embodiment

FIG. 14 shows a configuration of a non-volatile memory macro 302′ of a second embodiment. The same components as those in the first embodiment are denoted by the same reference numerals and detailed description thereof will be omitted. Portions different from the first embodiment will be mainly described. In the second embodiment, a configuration of a high voltage generation circuit is different.

FIG. 15 shows a configuration of a high voltage generation circuit 1401. The configuration corresponds to a memory macro that continuously writes four data. The comparator 1104 compares a voltage divided by a resistor 1502 with the standard voltage Vref generated by the standard voltage generation circuit 1101. A resistance voltage dividing ratio is made variable according to an address, so that an output voltage Vp is made variable. Specifically, regarding first to fourth addresses where write verify is performed by a decoder 1501, a switch 1503 is turned on at a first address (an address where write is performed for the first time), a switch 1504 is turned on at a second address (an address where write is performed for the second time), a switch 1505 is turned on at a third address (an address where write is performed for the third time), and a switch 1506 is turned on at a fourth address (an address where write is performed for the last time).

Thereby, when a total sum of resistance values of the resistor 1502 is R(=R₁+R₂+R₃+R₄+R₅), an output voltage Vp in the case of the first address is Vref×R/(R₁+R₂+R₃+R₄), an output voltage Vp in the case of the second address is Vref×R/(R₁+R₂+R₃), an output voltage Vp in the case of the third address is Vref×R/(R₁+R₂), and an output voltage Vp in the case of the fourth address is Vref×R/R₁. In this way, as the address of continuous data to be written advances, the resistance voltage dividing ratio changes and the output voltage Vp rises.

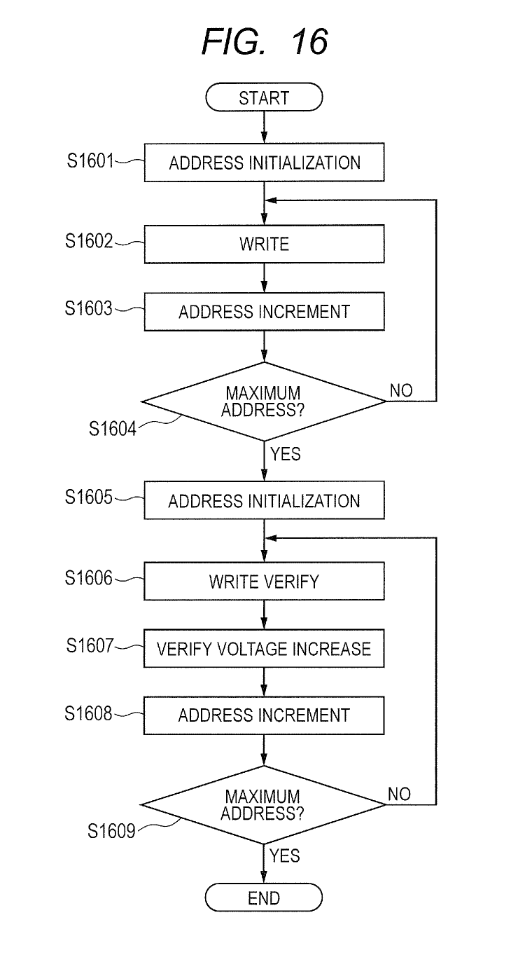

FIG. 16 shows a flowchart executed by the non-volatile memory control circuit 301 when a multiple data continuous write is performed on the non-volatile memory macro 302′ in the semiconductor device 300. First, an address is set to a write start address (S1601), and write (S1602) and address increment (S1603) are repeated the number of times of the number of write data (S1604). When predetermined continuous data write is completed, the address is set to the write start address again (S1605), and write verify (S1606) and address increment (S1608) are repeated the number of times of the number of write data (S1609). Here, in the write verify, it is controlled so that as the address advances, the verify voltage applied to the word line VL rises (S1607).

As described above by using FIG. 2, the memory cell threshold value from the write operation completion varies with time. In the multiple data continuous write in the second embodiment, the verify voltage applied to the word line WL (that is, a voltage applied to the gate of a memory cell during the write verify) is raised for a memory cell of an address where the write is performed later, so that comparison with the reference current is performed in a state in which a larger amount of read current flows than the amount of current flowing through a memory cell of an address where write is performed earlier. In other words, the write verify is performed on the memory cell of an address where the write is performed later in a severer condition than the memory cell of an address where the write is performed earlier. In this way, the effect of the time variation of the memory cell threshold value from the write operation completion is cancelled by a write verify condition, so that it is possible to perform the write verify under substantially the same condition on a memory cell of each address where the write is continuously performed.

### Third Embodiment

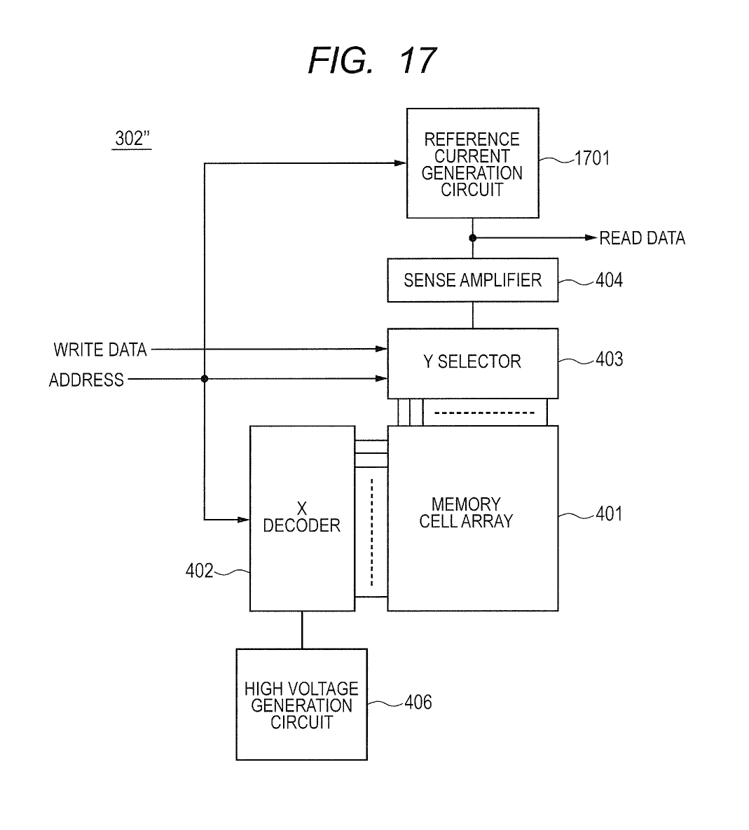

FIG. 17 shows a configuration of a non-volatile memory macro 302″ of a third embodiment. The same components as those in the first embodiment are denoted by the same reference numerals and detailed description thereof will be omitted. Portions different from the first embodiment will be mainly described. In the third embodiment, a configuration of a reference current generation circuit is different.

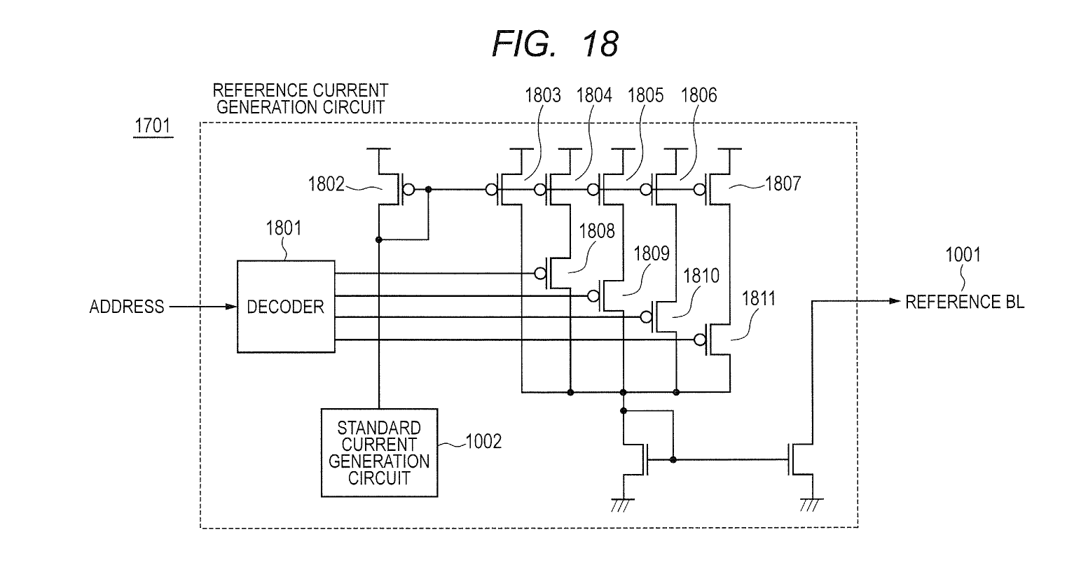

FIG. 18 shows a configuration of a reference current generation circuit 1701. The configuration corresponds to a memory macro that continuously writes four data. It is configured so that as the address advances, a current mirror ratio of a current mirror changes and the reference current decreases. Specifically, regarding first to fourth addresses where the write verify is performed by a decoder 1801, switches 1808 to 1811 are turned on at a first address (an address where write is performed for the first time), switches 1808 to 1810 are turned on at a second address (an address where write is performed for the second time), switch 1808 and 1809 are turned on at a third address (an address where write is performed for the third time), and the switch 1808 is turned on at a fourth address (an address where write is performed for the last time). The switches 1808 to 1811 are turned ON, so that a current corresponding to a mirror ratio with a P-type MOS transistor 1802 flows in source-drain paths of P-type MOS transistors 1804 to 1807 serially coupled to the switches 1808 to 1811, respectively, and thereby the amount of reference current changes.

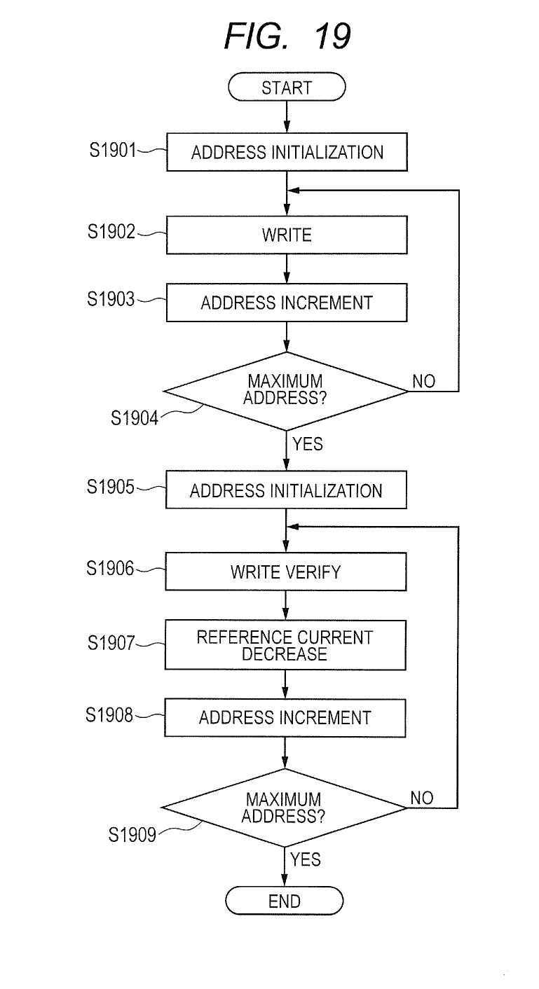

FIG. 19 shows a flowchart executed by the non-volatile memory control circuit 301 when a multiple data continuous write is performed on the non-volatile memory macro 302″ in the semiconductor device 300. First, an address is set to a write start address (S1901), and write (S1902) and address increment (S1903) are repeated the number of times of the number of write data (S1904). When predetermined continuous data write is completed, the address is set to the write start address again (S1905), and write verify (S1906) and address increment (S1908) are repeated the number of times of the number of write data (S1909). Here, in the write verify, it is controlled so that as the address advances, the reference current decreases (S1907).

As described above by using FIG. 2, the memory cell threshold value from the write operation completion varies with time. In the multiple data continuous write in the third embodiment, by decreasing the reference current for a memory cell of an address where the write is performed later, if the memory cell threshold value of the memory cell of the address where the write is performed later is not higher than the memory cell threshold value of a memory cell of an address where the write is performed earlier, the cell current exceeds the reference current and the memory cell is determined as an erase cell. In other words, the write verify is performed on the memory cell of an address where the write is performed later in a severer condition than the memory cell of an address where the write is performed earlier. In this way, the effect of the time variation of the memory cell threshold value from the write operation completion is cancelled by a write verify condition, so that it is possible to perform the write verify under substantially the same condition on a memory cell of each address where the write is continuously performed.

While the invention made by the inventors has been specifically described based on the embodiments, it is needless to say that the present invention is not limited to the embodiments and may be variously modified without departing from the scope of the invention. For example, the greater the number of rewriting times, the greater the amount of variation of the memory cell threshold value immediately after a write operation. Therefore, in the second and the third embodiments, the number of rewriting times may be stored, and the amount of variation for determination may be increased for each address according to the number of rewriting times. In this case, the above operation can be realized by increasing an adjustment margin of a resistance voltage dividing ratio of the resistor 1502 in FIG. 15 according to an assumed amount of variation, or increasing an adjustment margin of the mirror ratio in FIG. 18 according to an assumed amount of variation.

What is claimed is:

1. A semiconductor device comprising:
a non-volatile memory circuit; and
a non-volatile memory control circuit that controls the non-volatile memory circuit,
wherein the non-volatile memory circuit continuously performs a write operation on memory cells of a plurality of addresses of the non-volatile memory circuit and thereafter performs a write verify operation on the memory cells of the addresses where the write operation has been performed, and
wherein the non-volatile memory control circuit performs control so that a cycle of performing a write operation on one memory cell in the above write operation and a cycle of performing a write verify operation on one memory cell in the above write verify operation are the same.

2. The semiconductor device according to claim 1,
wherein the memory cell is a floating gate type memory cell or a MONOS type memory cell.

3. The semiconductor device according to claim 1,
wherein the non-volatile memory circuit has a plurality of word lines extending in a first direction, a plurality of source lines extending in the first direction, a plurality of bit lines extending in a second direction different from the first direction, and a memory cell array where memory cells, in each of which a gate of the memory cell is coupled to the word line, a source of the memory cell is coupled to the source line, a drain of the memory cell is coupled to the bit line, are arranged in an array form, and
wherein the memory cells of the addresses of the non-volatile memory circuit where the non-volatile memory control circuit continuously performs the write operation are memory cells commonly coupled to any one of the source lines.

4. A semiconductor device comprising:
a non-volatile memory circuit; and
a non-volatile memory control circuit that controls the non-volatile memory circuit,
wherein the non-volatile memory circuit continuously performs a write operation on memory cells of addresses from a first address to an nth address (n is an integer) of the non-volatile memory circuit and thereafter performs a write verify operation on the memory cells of the addresses from the first address to the nth address where the write operation has been performed, and
wherein in the write verify operation, as the address advances from the first address to the nth address, a determination condition is made severer.

5. The semiconductor device according to claim 4,
wherein the memory cell is a floating gate type memory cell or a MONOS type memory cell.

6. The semiconductor device according to claim 4,
wherein the non-volatile memory circuit has a plurality of word lines extending in a first direction, a plurality of source lines extending in the first direction, a plurality of bit lines extending in a second direction different from the first direction, and a memory cell array where memory cells, in each of which a gate of the memory cell is coupled to the word line, a source of the memory cell is coupled to the source line, a drain of the memory cell is coupled to the bit line, are arranged in an array form, and
wherein the memory cells of a plurality of addresses of the non-volatile memory circuit where the non-volatile memory control circuit continuously performs the write operation are memory cells commonly coupled to any one of the source lines.

7. The semiconductor device according to claim 6,
wherein the non-volatile memory circuit has a voltage generation circuit that generates a write verify voltage to be supplied to a driver that drives the word line, and
wherein in the voltage generation circuit, the generated write verify voltage is raised as the address advances from the first address to the nth address.

8. The semiconductor device according to claim 7,
wherein an amount of change of the generated write verify voltage is increased as the address advances from the first address to the nth address according to the number of times of rewriting to the non-volatile memory circuit.

9. The semiconductor device according to claim 6,
wherein the non-volatile memory circuit has a reference current generation circuit that generates a reference current and a sense amplifier that compares a current flowing to a memory cell selected in the write verify operation and the reference current, and
wherein in the reference current generation circuit, the generated reference current is decreased as the address advances from the first address to the nth address.

10. The semiconductor device according to claim 9,
wherein in the write verify operation, the same voltage as that used in a reading operation of a memory cell is applied to the word line.

11. The semiconductor device according to claim 9,
wherein an amount of change of the generated reference current is increased as the address advances from the first address to the nth address according to the number of times of rewriting to the non-volatile memory circuit.
